(19) United States
(12) Patent Application Publication
(10) Pub. No.: US 2009/0242236 A1
(43) Pub. Date: Oct. 1, 2009

(54) METHOD OF FORMING CONDUCTIVE TRACKS

(76) Inventors: John R. Fyson, London (GB); Sean D. Slater, Cambridgeshire (GB)

Correspondence Address: EASTMAN KODAK COMPANY;PATENT LEGAL STAFF, 343 STATE STREET, ROCHESTER, NY, 14650-2201, US

(21) Appl. No.: 12/066,398

(22) PCT Filed: Sep. 7, 2006
(86) PCT No.: PCT/GB06/03301

§ 371 Date: Jun. 16, 2008

(30) Foreign Application Priority Data
Sep. 13, 2005 (GB) 0518613.5

(51) Int. Cl. H05K 1/00; G03F 7/00; C25D 5/02

(52) U.S. Cl. 174/250; 430/315; 205/125

(57) ABSTRACT

A patterned electrical conductor having improved resolution and conductivity is obtained by forming a latent image by exposing, to pressure or sensitising radiation according to a desired conductive track pattern, a pressure-sensitive or photosensitive element having a support substrate and a pressure-sensitive or photosensitive material coated thereon, being capable of providing a latent image upon exposure and comprising a pressure-sensitive or photosensitive metal salt dispersed in a binder, which binder is susceptible to decomposition and/or dissolution upon treatment with an enzyme solution, developing the latent image to form a developed image formed by a first metal (e.g. silver) corresponding to the desired conductive track pattern, treating the developed image with an enzyme capable of decomposing or dissolving the binder and electroless plating and/or electroplating the developed metal image with a plating of a second metal (e.g. silver) to improve the conductivity of the developed metal image to form a conductive track according to the desired pattern, wherein the step of treating the developed image with the enzyme is prior to and/or during the plating step(s).

### FIELD OF THE INVENTION

The present invention relates to the formation of conductive materials as conductive tracks for and in electronic circuit boards and devices utilising such conductive tracks. The invention is particularly concerned with an improvement in the resolution of conductive metal tracks obtained by a photographic method, such as on a flexible support.

### BACKGROUND OF THE INVENTION

In the imaging, lighting, display and electronics industries it is predicted that in order to meet consumer demands, and fuelled by industry competitiveness, electronics products will be required to be increasingly durable, thin, lightweight and of low cost. In a growing market where consumers are demanding more from portable electronic devices and displays such as mobile phones, laptop computers, etc., flexible displays and electronics have the potential to eliminate the rigid constraints of traditional flat panel displays and electronics products. The goal in displays and electronics is to produce thin, lightweight, flexible devices and displays with achievable power requirements at a minimal cost.

Traditionally electronic devices requiring multiple layers of circuits have been fabricated using multiple circuit boards, with circuitry formed on one or both sides thereof, which may be bonded together and connected to one another by drilling holes (or vias) in the circuit boards which are filled with conductive material. To make such multiple layer circuit boards, a copper coated insulating board made of a composite material is treated with a light-sensitive material, known as a photoresist, which is imaged with the pattern of the desired electronic circuit, typically by exposing the photoresist through a photomask. The resist is affected by the exposure such that the exposed and non-exposed parts can be differentiated in terms of ease or method of removal. The imaged resist is then treated to remove the resist in an image-wise manner to reveal bare copper. The bared copper is then etched away and the remaining resist removed to reveal a copper track on the insulating board. A second board may be made in a similar way with its own circuit pattern and the two boards bonded together and optionally connected by drilling vias as mentioned above.

The process of making electronic circuit boards such as this can be quite laborious and involves several sequential steps.

It is desirable to provide a solution to improve the efficiency of the electronic circuit manufacturing process and to enable electronic circuits to be generated on flexible supports to meet the predicted growth in demand for flexible circuits and flexible and thin devices. A number of attempts to provide new manners of manufacturing electronic circuits have been previously disclosed, but the processes are often lengthy and laborious.

U.S. Pat. No. 3,839,038 describes a method that can be modified to make conducting tracks more or less continuously on a flexible support using imaging methods to lay down metals, particularly silver. The tracks made in this way have resistance that is too high for some purposes. This method creates a non-conducting image.

U.S. Pat. No. 6,706,165 describes a way of making metallic structures, which are presumably conducting, by forming a silver image which is then grown in an electroless plating bath to make it conductive and then electroplating this grown image to form the conducting metal structure. This process is relatively laborious and complicated. GB-A-0585035 describes a process for making conducting tracks, including an electroless plating process, which may or may not be followed by an electroplating step.

U.S. Pat. No. 3,223,525 describes a method of manufacturing, by photographic means, external electrically conductive noble-metal patterns on non-conductive supports. In the described method, a non-conductive support is treated with a light-sensitive compound such as silver halide, exposed to light to produce a silver or mercury germ image, which is then treated with a stabilised physical developer for a prolonged period of time, whereby the internal image is made to grow out beyond the surface of the support to become an external image having resistance of less than 10⁴ ohms per square.

U.S. Pat. No. 3,647,456 relates to a method of making electrically conductive silver images with the object of providing such silver images having high spatial resolution, which may be advantageously utilised in printed circuit techniques, thereby eliminating the need for an aluminium layer in photoresists and establishing a silver pattern directly upon a wafer. A coating of silver bromide emulsion comprising cadmium iodide is provided on a substrate to produce a latent image on the substrate, the latent image developed using a high resolution developer to provide a silver image and the silver image heated at a temperature of from 200° C. to 450° C. to render the silver image electrically conductive.

The various alternative methods of generating conductive circuit patterns illustrated in the above-referenced documents each has advantages as described therein, but do not provide a more efficient and improved method of manufacturing conductive tracks.

### PROBLEM TO BE SOLVED BY THE INVENTION

It is desirable to provide an efficient method of forming conductive tracks which involves fewer steps in fabrication as compared with traditional printed circuit board manufacture and which can be formed on flexible supports.

It is still further desirable to provide a method capable of forming conductive tracks or conductive areas having excellent conductivity and having gaps with very high resolution to meet the demands of increasingly complex circuitry of high-tech devices.

### SUMMARY OF THE INVENTION

According to a first aspect of the invention, there is provided a process for preparing a patterned electrical conductor comprising the steps of providing a pressure-sensitive or photosensitive element comprising a support substrate and a pressure-sensitive or photosensitive material coated onto the support, said material being capable of providing a latent image upon exposure to sensitising radiation and comprising a pressure-sensitive or photosensitive metal salt dispersed in a binder, which binder is susceptible to decomposition and/or dissolution upon treatment with an enzyme solution;

exposing the element to pressure or sensitising radiation according to a desired conductive track pattern to form a latent image on the element;
subjecting the latent image to a conventional development step to form a developed image formed by a first metal corresponding to the desired conductive track pattern;
treating said developed image with an enzyme capable of decomposing or dissolving the binder; and
electroless plating and/or electroplating said developed metal image with a plating of a second metal to improve the conductivity of said developed metal image to form a conductive track according to the desired pattern, wherein the step of treating the developed image with the enzyme is prior to and/or during the plating step(s).

In a second aspect of the invention, there is provided a patterned electrically conductive element comprising a conductive track pattern on a support substrate, said element being obtainable by the above process.

In a third aspect of the invention, there is provided the use of an enzyme solution to improve the resolution of conductive tracks made by the above process comprising the steps of providing said element; exposing said element to pressure or sensitising radiation according to a desired conductive track pattern to form a latent image thereon; subjecting the latent image to a conventional development step to form a developed image formed by a first metal corresponding to the desired conductive track pattern; and electroless plating and/or electroplating said developed metal image with a plating of a second metal to improve the conductivity of said developed metal image to form a conductive track according to the desired pattern, by treating the developed image with the enzyme solution prior to and/or during plating.

### ADVANTAGEOUS EFFECT OF THE INVENTION

The process of preparing a patterned electrical conductor according to the invention provides a quicker, more efficient method of manufacturing conductive tracks, which may be formed on a flexible support. In particular, the step of treating the developed image with an enzyme prior to or during plating the developed image enables conductive tracks with improved conductivity, higher resolution (tracks and gaps) and reduced susceptibility to unwanted circuit-shorting to be generated. The method may therefore find particular utility in the formation of conductive tracks having tightly controlled conductivity, track width and gap width according to the desired utility.

### BRIEF DESCRIPTION OF THE DRAWINGS

FIG. 1 is a diagrammatical representation of a wash-and-plating process carried out on a developed metal image, which process does not comprise an enzyme treatment step.

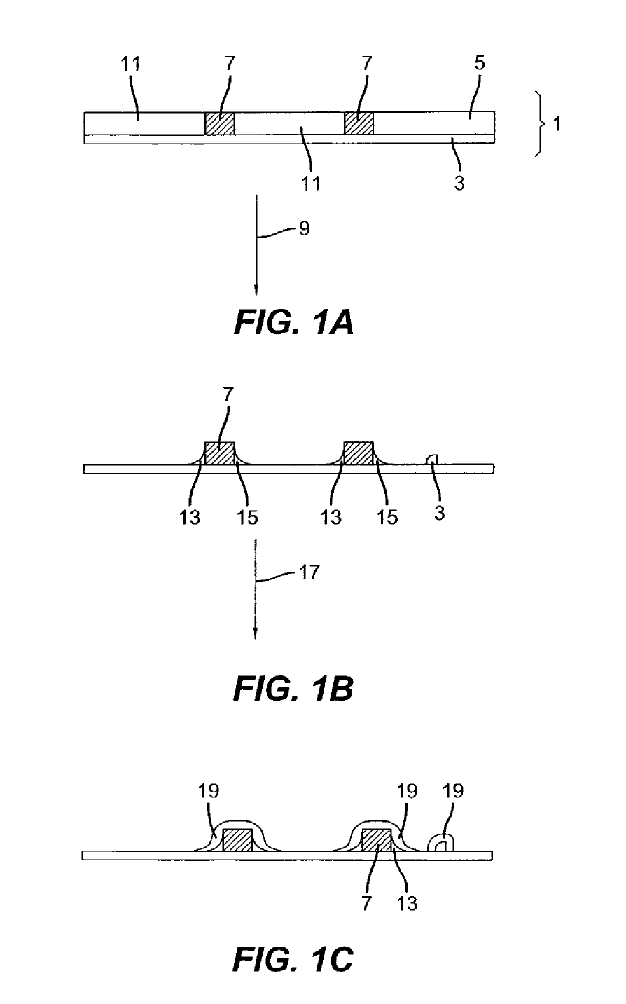

FIG. 2 is a diagrammatical representation of a process similar to that represented by FIG. 1, where an enzyme treatment step is carried out.

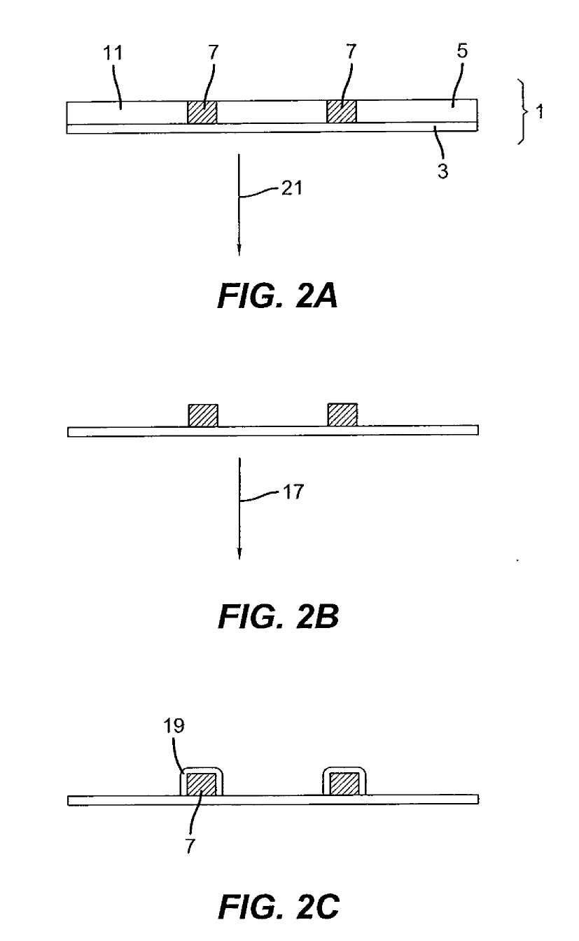

### DETAILED DESCRIPTION OF THE INVENTION

The process of the present invention involves generating a latent image through exposure of a pressure-sensitive or photosensitive metal salt in a binder according to a desired pattern, followed by development to form a corresponding metal image. In order to improve the form and conductivity of the metal image, it is desirable to plate the metal image by electroless plating (i.e. physical development) and/or electroplating (i.e. electrochemical development). Preferably, the developed metal image is capable of carrying a current (i.e. is conductive) and can be electroplated without needing an electroless plating step.

It has been found by the inventors that the binder composition used in the element upon which the latent image is formed is often slightly conductive itself. This has the effect that, in non-imaged areas, residual binder composition may be plated in addition to the developed metal image.

For example, where a metal (e.g. silver) image 7 is formed on an element 1 comprising an unhardened gelatin composition 5 coated on a support 3, a wash step 9 is typically applied as part of the conventional development process, which washes away most of the gelatin from the non-imaged portions 11 of the element 1. However, residual gelatin 13 tends to remain, especially at the juncture 15 of the metal tracks 7 and the support 3, due to the inaccessibility of that location and the possible cross-linking of gelatin by oxidised developer composition. When subjected to a physical or electrochemical plating step 17, the plating 19 encompasses the metal image 7 as well as the residual gelatin 13 (due to the slight conductivity of the gelatin composition in electroplating, for example) which has the effect of increasing the track width and reducing the gap width (i.e. reduction in resolution) as well as increasing the likelihood of short-circuits occurring.

Where, for example, a hardened binder composition is used (e.g. hardened gelatin), plating of the developed metal image also results in a small amount of plating on the non-imaged portions of the element, which can lead to short-circuits occurring.

The inventors have found that by treating the developed metal image 7 with an enzyme 21 capable of decomposing or dissolving the binder prior to and/or during plating the metal tracks, unwanted residual binder composition 13 can be substantially removed, so that the plating step 17 is limited to plating 19 of the metal tracks 7 themselves, which leads to improved track and gap resolution, improved conductivity and reduced likelihood of shorts occurring.

The enzyme used is selected according to the binder in the element in which the conductive tracks are formed and may be selected depending upon the activity of a certain enzyme with the binder being used. The enzyme is typically used as a solution in which the developed metal image is immersed (or may be provided as a thin process coating). Another consideration in the choice of enzyme is the pH at which the enzyme works. The choice of enzyme may therefore be affected by the pH of the plating solution or of the wash/fix solution, especially if the enzyme treatment step is to be carried out within another step.

The amount of enzyme and the concentration of the solution used depends upon several factors, such as the activity of the enzyme on the binder used, whether or not the binder has been hardened or cross-linked, the pH of the enzyme solution and the duration of treatment. The amount of enzyme used and the duration of treatment may be altered as appropriate to maximise the effect of the residual binder removal process, whilst ensuring the track pattern is not disrupted (since it is bound to the support by the binder composition itself). Typically, for use with an exposed and developed high silver/low gelatin element, an enzyme solution (whether as part of a plating solution or not) comprises from 0.5 to 20 g/l of enzyme, preferably 1 to 10 g/l, and the duration of treatment is from 10 seconds to 10 minutes, preferably 30 seconds to 3 minutes. Typically, the enzyme treatment will be carried out at 40° C. or below.

The substrate upon which the pressure-sensitive or photosensitive material utilised may be coated depends upon the intended utility. The substrate may be rigid or flexible, transparent or opaque, but is preferably flexible. Suitable such substrates include, for example, glass, glass-reinforced epoxy laminates, cellulose triacetate, metal pads and semiconductor components, adhesive-coated polymer substrates, printed circuit board (PCB) substrates including polymer-based PCBs, ceramic substrates, polymer tapes (e.g. dielectric green tape for multi-layer ceramic devices), paper, gloss art paper, bond paper, semi-synthetic paper (e.g. polyester fibre), synthetic paper (e.g. Polyart™), resin-coated paper, polymer substrates and composite materials. Suitable polymers for use as polymer substrates include polyethylene, especially polyethylene terephthalate (PET) and polyethylene naphthalate (PEN), polypropylene, polyester, polyamide, polyimide, polysulfone and mixtures thereof. The substrate, especially a polymer substrate, may be treated to improve adhesion of the silver halide emulsion to the substrate surface. For example, the substrate may be coated with a polymer adhesive layer or the surface may be chemically treated or subjected to a corona treatment.

For coating onto a substrate in the manufacture of flexible electronic devices or components, the support is preferably flexible, which aids rapid roll-to-roll application.

An Estar® PET support or a cellulose triacetate support is preferable. Alternatively, the support may be the same support used in a flexible display device, by which it is meant that a pressure-sensitive or photosensitive coating may be coated onto the back of a support for a display device and imaged in situ according to a desired pattern and processed in situ.

Where a discrete support is utilised (i.e. the support is not the reverse side of a support for a flexible display device), it can be coated with a pressure-sensitive and/or photosensitive layer on either side or both sides, provided that either the same pattern is desired for both sides or the support is such that formation of the latent image on one side of the support will not fog the coating on the other side of the support.

The pressure-sensitive or photosensitive material may be any suitable material capable of providing a latent image (i.e. a germ or nucleus of metal in each exposed grain of metal salt) according to a desired pattern upon pressure or photo exposure, and that comprises a pressure-sensitive or photosensitive metal salt which is developable into a metal image and a binder which is susceptible to decomposition and/or dissolution upon treatment with an appropriate enzyme.

Preferably, the binder is a hydrophilic colloid such as gelatin or gelatin derivative, polyvinylpyrrolidone or casein and may contain a polymer. Suitable hydrophilic colloids and vinyl polymers and copolymers are described in Section IX of Research Disclosure Item 36544, September 1994, published by Kenneth Mason Publications, Emsworth, Hants, PO10 7DQ, UK. The preferred hydrophilic colloid is gelatin.

The enzyme is selected according to the binder used in the pressure-sensitive or photosensitive material. Where the binder is a proteinic binder such as gelatin, the enzyme is preferably a protease. Suitable protease enzymes include papain, trypsin, HT-200 protease (from Genencor), GC1106 protease—a high pH working enzyme (from Genencor) and Takamine (Takadiastrase).

The pressure-sensitive or photosensitive metal salt is preferably selected from salts of copper, nickel, gold, platinum and silver. Metal salts with an oxidation state of +1 are preferred and particularly preferred are silver (I) salts, preferably silver halides.

The silver halide may be, for example, silver chloride, silver bromide, silver chlorobromide or silver bromoiodide. Preferably, the silver halide dispersion (or emulsion as it is called in the photographic arts) in the binder is a high contrast silver halide emulsion, which is suitable for use in the graphic arts and in manufacturing PCBs, for example. The silver halide emulsion is preferably a chlorobromide emulsion, preferably comprising at least 50 mol % silver chloride, more preferably 60-90 mol % silver chloride and most preferably 60-80 mol % silver chloride. The remainder of the silver halide is preferably substantially made up of silver bromide and more preferably comprises a small proportion (e.g. up to 1 or 2%) of silver iodide. Preferably the silver halide is present in an amount of at least 1 g/m².

Preferably, the pressure-sensitive or photosensitive material is a high metal (e.g. silver)/low binder (e.g. gelatin) material, so that after conventional development it is sufficiently conductive to enable direct electroplating of the metal pattern formed. In this regard, a preferred ratio of binder to metal in the pressure-sensitive or photosensitive material is in the range of from 0.1 to 0.7, more preferably from 0.2 to 0.6.

The first metal is the corresponding metal of the pressure-sensitive or photosensitive metal salt and accordingly the first metal is preferably silver.

Preferably, the material is a photosensitive material.

According to the preferred embodiment, where the metal salt is a photosensitive metal salt, preferably silver halide, the metal may be sensitised to any suitable wavelength of the exposing radiation, as desired, but is preferably sensitised to light of the wavelengths emitted by solid state diode red light sources commonly used in imagesetters and photoplotters. Preferably, the metal salt dispersion is a silver halide emulsion sensitised to light in the range 600-690 nm.

The amount of sensitising dye used in a silver halide emulsion is preferably in the range of 50 to 1000 mg per mol equivalent of silver (mg/Agmol), more preferably 100 to 600 mg/Agmol and still more preferably 150 to 500 mg/Agmol. It is most preferable to incorporate the sensitising dye into the silver halide emulsion in an amount of from 300 to 500 mg/Agmol.

The emulsions employed in the materials described herein, and the addenda added thereto, the binders, etc., may be as described in Research Disclosure Item 36544, September 1994, published by Kenneth Mason Publications, Emsworth Hants, PO10 7DQ, UK.

The photosensitive materials described herein preferably include an antihalation layer that may be on either side of the support, preferably on the opposite side of the support from the photosensitive layer. In a preferred embodiment, an antihalation dye is contained in an underlayer of a hydrophilic colloid. Suitable dyes are listed in the Research Disclosure above.

The silver halide emulsions referred to may be prepared by any common method of grain growth, preferably using a balanced double run of silver nitrate and salt solutions using a feedback system designed to maintain the silver ion concentration in the growth reactor. Dopants may be introduced uniformly from start to finish of precipitation or may be structured into regions or bands within the silver halide grains. Dopants, for example osmium dopants, ruthenium dopants, iron dopants, rhenium dopants or iridium dopants, for example cyanoruthenate dopants, may be added, preferably a combination of osmium and iridium dopants, preferably an osmium nitrosyl pentachloride dopant (especially in combination with a red-sensitising trinuclear merocyanine dye). Such complexes may alternatively be utilised as grain surface modifiers in the manner described in U.S. Pat. No. 5,385,817. Chemical sensitisation may be carried out by any of the known methods, for example with thiosulfate or other labile sulfur compound and with gold complexes. Preferably, the chemical sensitisation is carried out with thiosulfate and gold complexes.

The silver halide grains may be cubic, octahedral, rounded octahedral, polymorphic, tabular or thin tabular emulsion grains, preferably cubic, octahedral or tabular grains. Such silver halide grains may be regular untwinned, regular twinned, or irregular twinned with cubic or octahedral faces. The silver halide grains may also be composed of mixed halides.

In cases where the emulsion composition is a mixed halide, the minor component may be added in the crystal formation or after formation as part of the sensitisation or melting. The emulsions may be precipitated in any suitable environment such as a ripening environment, a reducing environment or an oxidising environment.

Specific references relating to the preparation of emulsions of differing halide ratios and morphologies are Evans U.S. Pat. No. 3,618,622, Atwell U.S. Pat. No. 4,269,927, Wey U.S. Pat. No. 4,414,306, Maskasky, U.S. Pat. No. 4,400,463, Maskasky U.S. Pat. No. 4,713,323, Tufano et al, U.S. Pat. No. 4,804,621, Takada et al U.S. Pat. No. 4,738,398, Nishikawa et al U.S. Pat. No. 4,952,491, Ishiguro et al U.S. Pat. No. 4,493,508, Hasebe et al U.S. Pat. No. 4,820,624, Maskasky U.S. Pat. Nos. 5,264,337 and 5,275,930, House et al U.S. Pat. No. 5,320,938 and Chen et al U.S. Pat. No. 5,550,013, Edwards et al U.S. Ser. No. 08/362,283 filed on Dec. 22, 1994 and U.S. Pat. Nos. 5,726,005 and 5,736,310.

Antifoggants and stabilisers may be added after addition of sensitising dye to give the emulsion the desired sensitivity, if appropriate, as is known in the art. Antifoggants that may be useful include, for example, azaindenes such as tetraazaindenes, tetrazoles, benzotriazoles, imidazoles and benzimidazoles. Specific antifoggants that may be used include 5-carboxy-2-methylthio-4-hydroxy-6-methyl-1,3,3a,7-tetraazaindene, 1-(3-acetamidophenyl)-5-mercaptotetrazole, 6-nitrobenzimidazole, 2-methylbenzimidazole and benzotriazole.

Nucleators and, preferably, development boosters may be used to give ultra-high contrast, for example combinations of hydrazine nucleators such as those disclosed in U.S. Pat. No. 6,573,021, or those hydrazine nucleators disclosed in U.S. Pat. No. 5,512,415 at col. 4, line 42 to col. 7, line 26, the disclosures of which are incorporated herein by reference. Booster compounds that may be present in the photographic material (or alternatively, in the developer solution used) include amine boosters that comprise at least one secondary or tertiary amino group and have an n-octanol/water partition coefficient (log P) of at least 1, preferably at least 3. Suitable amine boosters include those described in U.S. Pat. No. 5,512,415, col. 7, line 27 to col. 8, line 16, the disclosure of which is incorporated herein by reference. Preferred boosters are bis-tertiary amines and bis-secondary amines, preferably comprising dipropylamino groups linked by a chain of hydroxypropyl units, such as those described in U.S. Pat. No. 6,573,021. Any nucleator or booster compound utilised may be incorporated into the silver halide emulsion or alternatively may be present in a hydrophilic colloid layer, preferably adjacent the layer containing the silver halide emulsion for which the effects of the nucleator are intended. They may, however, be distributed between or among emulsion and hydrophilic colloid layers, such as undercoat layer, interlayers and overcoat layers.

Preferably, a photosensitive silver halide material such as that described in U.S. Pat. No. 5,589,318 or U.S. Pat. No. 5,512,415 is utilised.

The latent image formed in the process of the invention is subjected to a conventional development step, whereby a developed image of a first metal according to the latent image is formed.

The conventional development step comprises treating the latent image with a developer composition, which may be incorporated in the coating, but requiring activation (e.g. by heating, i.e. thermal development, or changing pH), or may be added as a solution as part of a development process. The developer composition typically comprises a reducing agent capable of reducing the metal salt to the elemental metal, when catalysed by the elemental particles of the latent or germ image under the conditions of the development process.

The development step may further comprise fixing the image by treating the developed image with a fixer composition and/or a wash step, whereby the active fixer and developer components are removed and the majority of unhardened binder (e.g. gelatin) in the non-imaged areas is removed, although a residue typically remains around the tracks. Optionally, the enzyme solution can be incorporated into the fixer and/or wash solutions or added toward the end of the fixing or washing steps.

In a preferred embodiment, where the metal salt is a pressure-sensitive or photosensitive silver halide, it may be processed following exposure to form a visible image by associating the silver halide with an aqueous alkaline medium in the presence of a developing agent contained in the medium or in the material itself. The material may be processed in conventional developers to obtain very high contrast images. When the material contains an incorporated developing agent, it can be processed in the presence of an activator, which may be identical to the developer in composition, but lacking a developing agent.

The developers are typically aqueous solutions, although organic solvents, such as diethylene glycol, can also be included to facilitate the solution of organic components. The developers contain one or a combination of conventional developing agents, such as for example, a polyhydroxybenzene such as dihydroxybenzene, aminophenol, a paraphenylenediamine, ascorbic acid, erythorbic acid and derivatives thereof, pyrazolidone, pyrazolone, pyrimidine, dithionite and hydroxylamine.

It is preferred to employ hydroquinone and 3-pyrazolidone developing agents in combination or an ascorbic acid-based system in the development of silver halide latent images. An auxiliary developing agent exhibiting super-additive properties may also be used. The pH of the developers can be adjusted with alkali metal hydroxides and carbonates, borax and other basic salts. It is a particular advantage that the use of nucleators as described herein reduces the sensitivity of photosensitive material to changes in this developer pH.

To reduce swelling of a hydrophilic binder (e.g. gelatin) during development, compounds such as sodium sulfate may be incorporated into the developer. Chelating and sequestering agents, such as ethylenediamine tetraacetic acid or its sodium salt, can be present. Generally any conventional developer can be used in the practice of this invention. Specific illustrative photographic developers are disclosed in the Handbook of Chemistry and Physics, 36^{th} Edition, under the title “Photographic Formulae” at page 30001 et seq. and in “processing Chemicals and Formulas”, 6^{th} Edition, published by Eastman Kodak Company (1963).

The developed image may be subjected to an electroless plating (or physical development step), by which it is meant that the metal image formed by conventional development is treated with a solution of a metal salt or complex of the same, or different, metal as that formed by conventional development of the latent image.

Preferably, the developed image is subjected to an electroplating step (or electrochemical development), optionally after electroless plating, by which it is meant that a conductive metal image formed by conventional development and/or physical development has a voltage applied across it in the presence of a plating solution comprising a salt or complex of a plating metal, which may be the same or different from that of the metal image to be plated, whereby the conductive metal image is made more conductive. Suitable metals for use as the second metal (through electroless or electroplating) include, for example, copper, lead, nickel, chromium, zinc, gold and silver, preferably copper or silver and most preferably silver.

In the method of the invention, the exposed pressure-sensitive or photosensitive element is developed by applying a conventional development step followed by an electroless plating step and/or an electroplating step. Where the development of the exposed pressure-sensitive or photosensitive element comprises a conventional development step and an electrochemical development step (i.e. direct electroplating of a developed image), it is necessary that the image formed by conventional development is sufficiently conductive when a voltage is applied across it. In this case, it is preferable to use the electroplating technique described in our U.S. patent application Ser. No. 11/400,928 entitled, “Method of Forming Conductive Tracks”, which disclosure is incorporated herein by reference.

The electroplating step of the process is achieved by providing a plating solution in contact with the developed metal image whilst applying a voltage across the photographically generated pattern through the solution, by malting the photographically generated pattern the negatively charged electrode (referred to as the cathode in electrochemistry) in an electrochemical cell. The plating solution utilised according to the process of the invention may be, for example, a solution of a silver thiosulfate complex, e.g. Na₃Ag(S₂O₃)₂, where silver is the plating metal (the second metal), a solution of copper sulfate optionally with or without a polyethylene glycol PEG 200 where copper is the plating metal, nickel sulfate, i.e. NiSO₃, in the presence of boric acid where nickel is the plating metal, or zinc sulfate, ZnSO₄, where zinc is the plating metal. Preferably the plating solution has an equivalent concentration of the plating metal of from 0.01 to 2 molar, more preferably 0.03 to 0.5 molar and still more preferably 0.05 to 0.2 molar or 0.01 to 0.1 molar. Boric acid to control pH and/or PEG as a throwing agent may optionally be added to any of the plating solutions utilised.

The conductive patterns formed by the method of the invention preferably have a conductivity (expressed as resistivity) of 50 ohms/square or less, being achievable with the preferred silver halide emulsions and a conventional development step, more preferably 10 ohms/square or less, still more preferably 1 ohms/square or less. By exposing a coated support of the type used in the method of the invention to a desired pattern and processing the exposed layer with a conventional development step and a physical development step, a conductivity of 0.2 ohms/square is readily achievable. By further adopting a electrochemical development (electroplating) step, a conductivity of about 10 milliohms/square is achievable.

As mentioned above, silver is preferably the plating metal, so a solution of a silver salt or complex is preferably used. The silver salt is preferably a silver thiosulfate complex, e.g. Na₃Ag(S₂O₃)₂, and can be formed by making a solution of silver chloride, sodium sulfite and ammonium thiosulfate. Preferably, the silver plating solution has an equivalent concentration of silver of from 0.01 to 2 molar, more preferably 0.03 to 0.5 molar and still more preferably 0.05 to 0.2 molar or 0.01 to 0.1 molar. The low equivalent concentration of silver in the plating solution enables the plating process to be controlled, allowing even plating across the patterned conductor and minimising the build-up of plating metal close to the electronic contacts.

The formulation of metal salts for use in the plating solution may be adapted from any suitable plating solution formulation, a useful source of known plating solution formulations including “Modern Electroplating” 4^{th} Edn, Ed. M. Schlesinger, M. Pacinovic; published by Wiley.

Preferably, the patterned electrical conductor has a surface conductivity of 40 ohms/square or less. The voltage applied across the patterned conductor is preferably up to 2 V, more preferably up to 1 V.

Where the latent image is formed upon the coated support by applying pressure thereto according to a pattern, the degree of pressure to be applied is commensurate with the pressure-sensitivity of the coated support, which could depend upon the precise nature of the coated support and would be readily appreciated by the skilled person in the art. The method of applying pressure to generate a latent image is any suitable method by which a desired image can be applied, using any suitable pressurising device. For example, the latent image may be formed by applying pressure using a stylus (especially a high resolution stylus) or scalpel, an engraved stamp engraved according to the desired track pattern or a roller carrying a relief pattern according to the desired track pattern, such that latent images can be formed rapidly on a sequence of coated supports, especially flexible coated supports. Where the desired track pattern is a random conductive track pattern, the latent image may be formed by any suitable means of generating a random pattern such as by rubbing the surface of the coated support with steel wool.

The resolution of the conductive tracks formed depends primarily on the resolution of the pressurising or photo-imaging device. For many applications, it is preferred to form high resolution conductive tracks. Preferably, therefore, the conductive tracks formed have a line width of 50 μm or less, more preferably 25 μm or less or 20 μm or less, still more preferably 10 μm or less and most preferably 5 μm or less. Advantageously, for some applications, line widths of 1 or 2 μm may be formed and preferably for ease of use the line widths are at least 0.1 μm, preferably 0.5 μm wide.

According to an alternative embodiment where the latent image formed is heat-developed to generate tracks according to the desired track pattern, the pressure-sensitive or photosensitive material comprises a pressure-sensitive or photosensitive silver halide material and a secondary source of reducible silver ions in catalytic proximity thereto.

Preferably, according to this embodiment of the invention, the silver halide material comprises that described generally above or more particularly one or more silver halides (often referred to as photocatalysts in the photothermo-graphic (PTG) imaging arts) such as silver bromide, silver iodide, silver chloride, silver bromoiodide, silver chlorobromoiodide, silver chlorobromide and others readily apparent to one skilled in the art. Silver bromide and silver bromoiodide are more preferred, the latter silver halide including up to 10 mol % silver iodide.

The silver halide grains preferably utilised in this embodiment may have a uniform ratio of halide throughout, may have a graded halide content with a continuously varying ratio of, for example, silver bromide and silver iodide, or they may be of the core-shell type having a core of one halide ratio and a shell of another halide ratio. Core-shell silver halide grains useful in PTG materials and methods of preparing these materials are described, for example in U.S. Pat. No. 5,382,504, which disclosure is incorporated herein by reference, as are the relevant disclosures of U.S. Pat. No. 5,434,043, U.S. Pat. No. 5,939,249 and EP-A-0627660, which describe iridium and/or copper doped core-shell and non-core shell grains.

The secondary source of reducible silver ions may be any silver ion source suitable for use in PTG imaging and is preferably a non-photosensitive silver salt that forms a silver image when heated to 50° C. or higher in the presence of an exposed pressure-sensitive or photosensitive silver halide material and a developer composition. The secondary silver ion source may be, for example, one or more of silver benzotriazoles, silver oxalates, silver acetates and silver carboxylates, such as silver behenates, or any silver ion source selected from those described in EP-A-1191394 at page 23 line 17 to page 24, line 14, the disclosure of which is incorporated herein by reference. Preferably, the secondary silver ion source is a silver benzotriazole, suitable such benzotriazoles being disclosed in U.S. Pat. No. 3,832,186, the disclosure of which is incorporated herein by reference, or a silver soap, such a silver behenate, having a formula [Ag(CO₂CₓH₂ₓ₋₁)]₂, preferably where x=18-22.

In a heat-developable element that may be used according to this embodiment, it is preferred that the pressure-sensitive or photosensitive silver halide be present in an amount of from 0.005 to 0.5 mol per mol of secondary silver source, more preferably 0.01 to 0.15 mol and still more preferably 0.03 to 0.12 mol. It is also preferable that the pressure-sensitive or photosensitive silver halide be present in an amount of 0.5 to 15% by weight of the emulsion layer in which it is contained and more preferably from 1 to 10% by weight.

In this embodiment in which the latent image is developed through a heat development step, the secondary silver ion source and the silver halide material must be in catalytic proximity (i.e. in reactive association).

The emulsion of the silver halide material and secondary silver ion source may be prepared by any suitable method for use in PTG imaging. It is preferred that an ex situ method is used whereby the pressure-sensitive or photosensitive silver halide grains are preformed then added to and physically mixed with the silver ion source. Alternatively, the silver ion source is formed in the presence of ex situ-prepared silver halide, such as by co-precipitation of the silver ion source in the presence of silver halide to provide a more intimate mixture. The preformed silver halide emulsions or dispersions utilised in this method may be prepared by aqueous or organic processes and can be unwashed or washed to remove soluble salts. Alternatively, an in situ process in which a halide-containing compound is added to an organic silver salt to partially convert the silver of the organic silver salt to silver halide may be effective. The halogen-containing compound may be inorganic, such as zinc bromide or lithium bromide, or organic, such as N-bromosuccinimide. Additional methods of preparing the silver halide and organic silver salts and manners of blending them are described, for example, in Research Disclosure, June 1978, Item No. 17029, U.S. Pat. No. 3,700,458 and U.S. Pat. No. 4,076,539,

The pressure-sensitive or photosensitive silver halide material used according to this embodiment may be chemically sensitised and spectrally sensitised, if appropriate, by any suitable method known in the PTG art.

The developer composition, which may be incorporated into the coated support, may be any suitable developer for reducing the source of silver ions to metallic silver in PTG imaging systems. Suitable such developers include those described in EP-A-1191394 at page 24, line 18 to page 24, line 51, which disclosure is incorporated herein by reference. Particularly preferred developer compositions are the bisphenol class of PTG developers.

A development activator, also known as an alkali-release agent, base-release agent or an activator precursor, may be useful in the development of latent images according to the present embodiment. A development activator is an agent or compound which aids the developing agent, at processing temperatures, to develop a latent image in the imaging material. Useful development activators or activator precursors are described, for example, in Belgian Patent. No. 709, 967 published Feb. 29, 1968, and Research Disclosure, Volume 155, March 1977, Item 15567. Examples of useful activator precursors include guanidinium compounds such as guanidinium trichloroacetate, diguanidinium glutarate, succinate, malonate and the like; quaternary ammonium malonates; amino acids, such as 6-amino-caproic acid and glycine; and 2-carboxycarboxamide activator precursors.

Other addenda that may be incorporated into the coated support to be used in the PTG system according to this embodiment, include, for example, stabilisers, toners, anti-foggants, contrast-enhancers, development-accelerators, post-processing stabilisers or stabiliser precursors and other image-modifying agents, as would be readily apparent to the person skilled in the art. Heat transfer agents may also be incorporated.

The steps of treating the developed image with an enzyme, electroless plating and electroplating are largely as described above.

As mentioned above, the conductive tracks formed according to the method of the invention may form the electronic circuitry for various electronic devices. This may be in the form of a single layer of conductive tracks or multiple layers. Where more than two layers of circuitry are used, it is typically desirable to form electrical connections between the conductive patterns on each support or on each side of a support coated on both sides. One conductive pattern formed may be connected as desired to another conductive pattern formed by drilling holes or vias through the conductive element(s) and filling or coating the vias with a conductive material.

In a preferred embodiment of the present invention, the pressure-sensitive or photosensitive element has pressure-sensitive or photosensitive material coated onto each side of a support substrate. More preferably, the element is a photosensitive element such as that described in our PCT/GB2006/001099, the disclosure of which is incorporated herein by reference.

In particular, according to this embodiment, the photosensitive element comprises a first photosensitive layer sensitive to radiation of a first spectral region coated on one side of the support and a second photosensitive layer sensitive to radiation of a second spectral region coated on the other side of the support, whereby upon exposure to radiation of respective first and second spectral regions according to a desired pattern and development of the exposed photosensitive layers, the first and second photosensitive layers form developed metal images having a pattern of conductive tracks corresponding to the desired pattern. The first and second spectral regions may be the same, but are preferably different, or at least have different wavelengths of maximum absorption and little overlap. Where the support is transparent, the photosensitive layers may be imaged from the same side of the element. Chemical and spectral sensitisation and the male-up of the photosensitive layers are as described above.

This invention will now be described in more detail, without limitation, with reference to the following Examples and Figures.

### EXAMPLES

### Example 1

Samples of a Kodak™ Polychrome Graphics GRD film (a red-sensitive, high contrast graphics film used as a film intermediate in plate manufacture) were contact-exposed through a mask under an enlarger to give a fully exposed black line 1 mm wide and 65 mm long.

These film samples were processed in a graphic arts developer (formula set out below), diluted 1+2 with water, for 45 seconds at 21° C. and then fixed in Kodak™ 3000 fixer (formula set out below), diluted 1+3 with water, for 45 seconds also at 21° C.

These film samples (Samples 1-3) were then plated using three different processes (Processes 1-3). Sample 1 was subjected to a conventional physical development process. Sample 2 was subjected to a physical development process where the physical developer contained a proteolytic enzyme. Sample 3 was treated with a solution of a proteolytic enzyme and then subjected to a physical development process in which the physical developer contained the proteolytic enzyme. The processes and compositions used are set out in more detail below.

Physical developer (PD) (mixed 4 parts Part A and 1 part Part B before use).

Part A

| Water | 900 | ml |
|---|---|---|
| Ferric nitrate nonahydrate | 40 | g |
| Ammonium ferrous sulfate | 97.5 | g |
| Citric acid | 26.25 | g |
| warm to >25° C. | | |
| DDA* 10% | 12.5 | g |
| Triton X-200 (a nonyl phenyl | 1.5 | g |
| polyethylene glycol surfactant) | | |
| Water to | 1 | litre |
| Water | 90 | ml |
| Dodecylamine | 7.5 g (needed thawing) | |
| Acetic acid glacial. | 2.5 | g |

Part B

| Silver nitrate | 85 g (dissolved in 10 ml water) | |
|---|---|---|
| Water to | 1 | litre |

*DDA 10%

The enzyme-added physical developer used in Samples 2 and 3 was the above physical developer to which was added 5 g/l HT proteolytic 200 enzyme (supplied by Genencor International).

### Enzyme Solution (Pre-Physical Developer Bath)

| | |
|---|---|
| HT proteolytic 200 enzyme | 1 g |
| Water to | 1 litre |

### Processes 1-3:

### Process 1

Physical developer for 10 min. at 21° C.

### Wash for 2 min. at 21° C.

### Dry

### Process 2

Enzyme-added physical developer for 10 min. at 21° C.

### Wash for 2 min. at 21° C.

### Dry

### Process 3

Enzyme solution (pre-physical developer bath) for 10 s at 21° C.
Enzyme-added physical developer for 10 min. at 21° C.

### Wash for 2 min. at 21° C.

### Dry

After processing, the resistance along the track was measured using a resistance meter by applying the probes at the end of the track and making the necessary calculations to determine surface resistance. The results in each case are set out in TABLE 1.

TABLE 1

| Process | Resistance (ohm/square) | Comment |
|---|---|---|
| 1 (comp.) | 2.60 | Plating occurs on entire |
| | | surface. |
| 2 (inv.) | 1.57 | Unexposed gelatin fully |
| | | removed |
| 3 (inv.) | 0.62 | Unexposed gelatin fully |
| | | removed |

The results show that the inclusion of an enzyme in the process solutions decreases the resistance of the conducting tracks and effectively removes gelatin from unexposed parts of the film without disrupting the conductive tracks formed.

Formula of Developer Concentrate:

| | | |
|---|---|---|
| Demin. water | 500.00 | g |
| Potassium hydroxide (45.5%) | 62.25 | g |
| Sodium bromide | 15.00 | g |
| Sodium hydroxide (50%) | 11.60 | g |
| Phenylmercaptotetrazole | 0.38 | g |
| Hydroquinone | 75.00 | g |
| Potassium sulfite (45%) | 500.00 | g |
| Dimezone | 1.00 | g |
| 5-Mercaptobenzothiazole | 0.50 | g |
| Sodium carbonate 1H₂O | 50.00 | g |
| Ethylenediaminetetraacetic acid | 10.60 | g |
| Water to | 1 | litre |

| | |
|---|---|
| pH @25 Deg C. | 10.80 |

Formula of Fixer Concentrate:

| | | |
|---|---|---|
| Water | 90 | g |
| Acetic acid glacial. | 100 | g |
| Sodium hydroxide (50%) | 41 | g |
| Ammonium thiosulfate (56% w/w/) | 986 | g |
| Sodium metabisulfite | 23.5 | g |
| Water to | 1 | litre |

### Example 2 (Comparison)

A photographic film was prepared by coating a sulphur- and gold-sensitised 0.2 μm cubic silver bromochloride (AgBr_{0.3}Cl_{0.7}) in a binder system. The silver halide was sensitised to red light using potassium iodide and a sensitising dye: 5-[3-(carboxymethyl)-5-[2-methyl-1-[(3-methyl-2(3H)-benzothiazolylidene)methyl]propylidene]-4-oxo-2-thiazolidinylidene]-4-oxo-2-thioxo-3-thiazolidine acetic acid

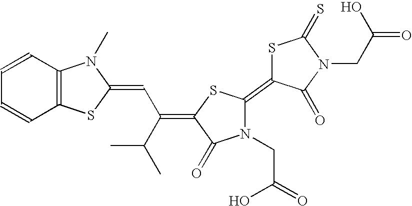

The silver laydown was 3.2 g/m². The binder system consisted of lime-processed ossein (LPO) gelatin at 1.5 g/m² and dextran (Mw 40,000) at 1 g/m². The emulsion was protected against fogging by the use of a tetra-azaindene: 7-hydroxy-5-methyl-2-(methylthio)-(1,2,4)triazolo(1,5-a) pyrimidine-6-carboxylic acid, a phenylmercaptotetrazole: N-(3-(2,5-dihydro-5-thioxo-1H-tetrazol-1-yl)-phenyl)acetamide (FOG-0901) and 2,3-dihydro-2-thioxo-4-thiazoleacetic acid.

The imaging layer was protected by a supercoat. This layer consisted of LPO gelatin at 0.5 g/m², polydimethylsiloxane lubricant at 0.45 mg/m², hydroquinone at 80 mg/m², a booster: dipropylamine at 60 mg/m², a nucleator: N-(3-(((4-(2-formylhydrazino)phenyl)amino)sulfonyl)-2,6-dimethyl-phenyl)-6,9,12,15-tetraoxa-3-thiatricosanamide,

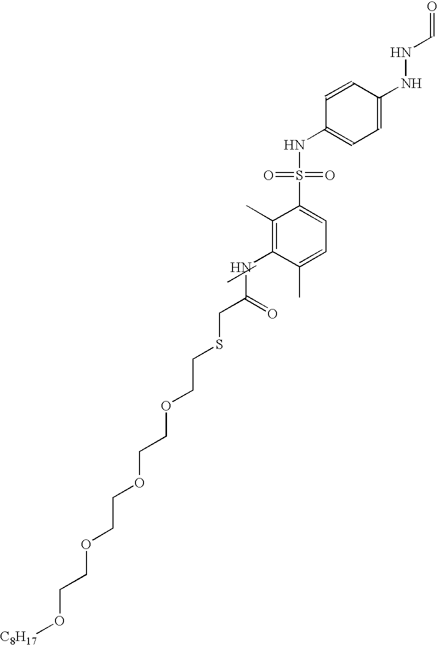

at 12.6 mg/m² and thickening and wetting agents to enable the two layers to be coated simultaneously onto a 7 thou (175 μm) clear polyester support (Estar™).

Such a film was then exposed on an Orbotech 7008m laser plotter. The image file consisted of lines 11 cm long, 5 mm wide, spaced at either 25 μm, 50 μm, 100 μm or 200 μm apart.

The film was developed in a tanning developer, which consisted of:

### Solution A

| | | |
|---|---|---|
| Pyrogallol | 10 | g |
| Sodium sulfite | 0.5 | g |
| Potassium bromide | 0.5 | g |
| Water to | 500 | ml |

### Solution B

| | | |
|---|---|---|
| Potassium carbonate | 50 | g |
| Water to | 500 | ml |

Just prior to use, A and B were mixed in a 1:1 ratio (i.e. 100 ml+100 ml). Development was for 7 min. at room temperature (21° C.). The film was then rinsed in cold water for 5 min., then washed in warm water to form the relief image. Gentle rubbing with cotton wool removed the gelatin from the non-imaged areas.

The film was then fixed to remove any undeveloped silver halide crystal which could be adhering to the image areas, washed again and then dried.

The conductivity of the silver tracks was enhanced by immersing the film in an electroless silver plating bath.

### Silver Plating Bath

| | | |
|---|---|---|
| Ferric nitrate | 32.32 | g |
| Ferrous ammonium sulfate | 78.42 | g |
| Citric acid | 21.0 | g |
| 0.01% Dodecylaminoacetate | 5 | ml |
| 0.01% Lissapol n/symperonic | 10 | ml |
| 5.722M Silver nitrate solution | 40 | g |
| water to | 1000 | g |

The immersion was for 10 min. at 21° C.

The conductivity of the tracks was measured and found to be 27 ohms, calculated to 1.23 ohms/square.

It was found that the lines that were spaced 25 μm apart had numerous shorts, but those that were spaced 50 μm apart had none. The resolution of this film was regarded as 50 μm.

### Example 3 (Invention)

Example 2 was repeated except that after the fixing step, the film was washed with a dilute enzyme bath. The enzyme bath was prepared by taking 6.3 g of Takamine powder dissolved in 1.3 l of demineralised water. After 1 h of stirring the material was filtered through a 3.0 μm filter, then through a 0.45 μm filter. The final bath was made up of 3 ml of concentrate diluted to 600 g with demineralised water. The film was washed with the enzyme bath for 1 min. at room temperature, which was sufficient for the desired enzymolysis to take place.

After the plating step, there were no shorts between the tracks and the resolution had increased to less than 25 μm. The plating step was so clean that it was possible to increase the temperature of the electroless plating bath to 40° C. The resistance of these tracks was less than 10 ohms (0.45 ohms per square). Thus, both the resolution and conductivity were improved.

1. A process for preparing a patterned electrical conductor comprising the steps of
providing a pressure-sensitive or photosensitive element comprising
a support substrate; and
a pressure-sensitive or photosensitive material coated onto said support, said material being capable of providing a latent image upon exposure to sensitising radiation and comprising a pressure-sensitive or photosensitive metal salt dispersed in a binder, said binder being susceptible to decomposition and/or dissolution upon treatment with an enzyme solution;
exposing element to pressure or sensitising radiation according to a desired conductive track pattern to form a latent image on said element;
subjecting the latent image to a conventional development step to form a developed image formed by a first metal corresponding to said desired conductive track pattern;
treating said developed image with an enzyme capable of decomposing or dissolving said binder; and
electroless plating said developed metal image with a plating of a second metal to improve the conductivity of said developed metal image to form a conductive track according to said desired pattern, wherein the step of treating the developed image with the enzyme is prior to and/or during said plating step(s).

2. A process as claimed in claim 1, wherein said binder is a proteinic binder.

3. A process as claimed in claim 2, wherein said binder is gelatin.

4. A process as claimed in claim 1, wherein said pressure-sensitive or photosensitive material comprises a silver halide emulsion in gelatin and said first metal is silver.

5. A process as claimed in claim 4, wherein said silver halide is present in an amount of at least 1 g/m².

6. A process as claimed in claim 1, wherein said second metal is selected from silver, gold, zinc, chromium, lead, copper of and nickel.

7. A process as claimed in claim 6, wherein said second metal is silver.

8. A process as claimed in claim 7, wherein said electroplating step comprises applying a voltage across the developed metal image in the presence of a solution of a silver thiosulfate complex.

9. A process as claimed in claim 8, wherein said silver thiosulfate solution is present in a concentration of from 0.01 to 0.1 molar.

10. A process as claimed in claim 1, wherein the developed image formed by said first metal is capable of conducting when a voltage is applied across it.

11. A patterned electrically conductive element comprising a conductive track pattern on a support substrate, said element being obtainable by the process of claims 1.

12. (canceled)

13. A process as claimed in claim 1, which comprises also electroplating said developed metal image with a plating of a second metal.

14. A process as claimed in claim 1, wherein said enzyme is a protease.
